(19) United States
(12) Patent Application Publication
(10) Pub. No.: US 2025/0314957 A1
(43) Pub. Date: Oct. 9, 2025

(54) PELLICLE MANUFACTURING METHOD

(71) Applicant: GrapheneLab.Co.,Ltd, Hwaseong-si (KR)

(72) Inventors: Gyu Hyun LEE, Yongin-si (KR); Young Duck KWON, Gwangmyeong-si (KR); Byong Wook YOO, Namyangju-si (KR); Seung Il MOON, Ansan-si (KR); Jong Taik MOON, Seongnam-si (KR); Ki Soo KIM, Seongnam-si (KR); Sang Min LEE, Yongin-si (KR)

(21) Appl. No.: 19/085,078

(22) Filed: Mar. 20, 2025

Related U.S. Application Data
(63) Continuation of application No. PCT/KR2022/019629, filed on Dec. 5, 2022.

(30) Foreign Application Priority Data
Oct. 11, 2022 (KR) 10-2022-0129368

(51) Int. Cl. G03F 1/62

(52) U.S. Cl. CPC G03F 1/62

(57) ABSTRACT

A pellicle manufacturing method includes forming a silicon nitride layer on each of the two sides of a wafer substrate; forming a nickel layer on one side of the silicon nitride layer formed on one side of the wafer substrate; forming an amorphous carbon layer on one side of the nickel layer; heating at a first heat treatment temperature so that interlayer exchange occurs between the amorphous carbon layer and the nickel layer, thereby forming a graphene layer; heating at a second heat treatment temperature so that the nickel layer aggregates, after the interlayer exchange step; and forming a plurality of holes in the graphene layer in a hydrogen gas atmosphere, after the nickel layer aggregation step.

### CROSS-REFERENCE TO RELATED APPLICATIONS

The present application is a Continuation of PCT/KR2022/019629 filed Dec. 5, 2022, which claims priority from Korean Application No. 10-2022-0129368 filed Oct. 11, 2022. The aforementioned applications are incorporated herein by reference in their entireties.

### TECHNICAL FIELD

The present disclosure relates to a pellicle manufacturing method.

### RELATED ART

Typically, photolithography methods are used when patterning semiconductor wafer substrates in manufacturing semiconductor devices and the like. In this case, a photomask is employed as an original plate for patterning in such a photolithography method.

While light is transmitted through a photomask, serving as the original plate for patterning, to transfer a pattern to a wafer substrate, when dust and the like are attached to this photomask, such dust absorbs or reflects the light. Accordingly, the mask pattern fails to be transferred to the wafer, or such a transferred pattern is damaged, leading to issues with deterioration in the performance of a semiconductor device or an increase in the defect rate. Even when such a process is performed in a clean room, there is a problem that dust and the like inevitably exist, making it challenging to prevent these issues from occurring.

As described above, to prevent dust from being attached to a photomask, methods of attaching a pellicle, which allows dust to attach to the pellicle, not directly to the surface of the photomask, have been used.

By attaching a pellicle, the light focus is positioned on a photomask pattern during lithography, so dust attached to the pellicle is unfocused and kept from being transferred as a pattern onto a wafer substrate.

In the meantime, while patterns formed by lithography become finer and finer as semiconductor devices and the like become more highly integrated, the wavelength of a light source becomes shorter and shorter to achieve this. Thus, methods using extreme ultraviolet (EUV) have recently been frequently proposed.

However, EUV has high energy, making the application thereof challenging by changing the physical properties of a thin pellicle, which is problematic. As a result, methods of manufacturing a pellicle by sequentially forming a monocrystalline or polycrystalline silicon layer serving as a core layer having a high EUV transmittance, a silicon nitride layer, and a capping layer on a silicon nitride layer on an upper side of a wafer substrate, applying a photoresist on a silicon nitride layer formed on a lower side of the wafer substrate, patterning the photoresist, removing the core of the silicon nitride layer through dry etching, and removing the core of the wafer substrate through wet etching to form a window through which EUV is transmitted have been recently employed.

In addition, research has also been conducted on methods using a graphene layer having a low EUV absorption rate and high thermal conductivity as a core layer.

However, to increase EUV transmittance in a pellicle, the thin film must be thin. Typically, a silicon nitride film deposited on a wafer substrate may be deposited to a thickness of about 100 nm, but depositing such a film to a smaller thickness is technically challenging. Even when deposited to a thickness of 100 nm or smaller, the technical limitation may be in the range of 10 to 50 nm. Still, there is no guarantee that such a limitation is reliable.

Furthermore, in actual pellicles being used, the silicon nitride layer must have a thickness of 5 nm or smaller, so methods of depositing a silicon nitride layer to a large thickness and then etching the silicon nitride layer again while being in a deposited membrane form are employed due the technical limitations. However, because the silicon nitride layer in the thin membrane form must be etched and formed to have a thickness of 5 nm or smaller, there have been problems that the success rate is significantly low and, thus, the yield of the pellicle is significantly low.

### SUMMARY

The present disclosure, which has been derived by solving the problems as described above, aims to provide a pellicle manufacturing method to maintain mechanical strength and improve transmittance characteristics.

A pellicle manufacturing method, according to a preferred embodiment of the present disclosure, is characterized by including: a silicon nitride layer formation step of forming first and second silicon nitride layers on both sides of a wafer substrate, respectively; a nickel layer formation step of forming a nickel layer on one side of the first silicon nitride layer formed on one side of the wafer substrate; an amorphous carbon layer formation step of forming an amorphous carbon layer on one side of the nickel layer; an interlayer exchange step of exchanging the amorphous carbon layer and the nickel layer through interlayer exchange by heating the resulting wafer substrate to a first heat treatment temperature, thereby forming a graphene layer; a nickel layer aggregation step of aggregating the nickel layer by heating the resulting wafer substrate to a second heat treatment temperature after the interlayer exchange step; and a hole formation step of forming a plurality of holes on the graphene layer in a hydrogen gas atmosphere after the nickel layer aggregation step.

Thus, according to the present disclosure, the pellicle manufacturing method based on one preferred embodiment of the present disclosure can improve transmittance characteristics while maintaining mechanical strength, can reduce costs and increase production efficiency because low-temperature direct growth and etching of graphene can be carried out in one chamber as a single process, and can improve pellicle characteristics without residues and defects caused by patterning and other coatings.

In the interlayer exchange step, the first heat treatment temperature may be in a temperature range of 400° C. to 600° C. in an argon gas atmosphere.

Thus, according to the present disclosure, the pellicle manufacturing method based on one preferred embodiment of the present disclosure can allow low-temperature direct growth and etching of graphene to be carried out in one chamber as a single process.

In the nickel layer aggregation step, the second heat treatment temperature may be in a temperature range of 800° C. to 1100° C.

Thus, according to the present disclosure, the pellicle manufacturing method based on one preferred embodiment of the present disclosure can allow low-temperature direct growth and etching of graphene to be carried out in one chamber as a single process.

The hole formation step may be carried out for 15 minutes or more in a temperature range of 800° C. to 1100° C. in a hydrogen gas atmosphere.

Thus, according to the present disclosure, the pellicle manufacturing method based on one preferred embodiment of the present disclosure can improve transmittance characteristics while maintaining mechanical strength.

The pellicle manufacturing method based on one preferred embodiment of the present disclosure may include a nickel removal step of removing nickel aggregates obtained by aggregating the nickel layer after the hole formation step.

Thus, according to the present disclosure, the pellicle manufacturing method based on one preferred embodiment of the present disclosure can reduce costs and increase production efficiency because low-temperature direct growth and etching of graphene can be carried out in one chamber as a single process and can improve pellicle characteristics without residues and defects caused by patterning and other coatings.

According to the present disclosure, a pellicle manufacturing method based on one preferred embodiment of the present disclosure can improve transmittance characteristics while maintaining mechanical strength.

According to the present disclosure, the pellicle manufacturing method based on one preferred embodiment of the present disclosure can reduce costs and increase production efficiency because low-temperature direct growth and etching of graphene can be carried out in one chamber as a single process.

According to the present disclosure, the pellicle manufacturing method based on one preferred embodiment of the present disclosure can improve pellicle characteristics without residues and defects caused by patterning and other coatings.

### BRIEF DESCRIPTION OF THE DRAWINGS

FIG. 1 is a flowchart illustrating a pellicle manufacturing method according to one embodiment of the present disclosure.

FIG. 2 is a conceptual diagram schematically illustrating a step of forming silicon nitride layers in a pellicle manufacturing method according to one embodiment of the present disclosure.

FIG. 3 is a conceptual diagram schematically illustrating a step of forming a nickel layer and an amorphous carbon layer in a pellicle manufacturing method according to one embodiment of the present disclosure.

FIG. 4 is a conceptual diagram schematically illustrating an interlayer exchange step in a pellicle manufacturing method according to one embodiment of the present disclosure.

FIG. 5 is a conceptual diagram schematically illustrating a nickel layer aggregation step in a pellicle manufacturing method according to one embodiment of the present disclosure.

FIG. 6 is a conceptual diagram schematically illustrating a hole formation step in a pellicle manufacturing method according to one embodiment of the present disclosure.

### DETAILED DESCRIPTION

The above and other objectives, features, and advantages of the present disclosure may be readily understood through the following preferred embodiments associated with the accompanying drawings. However, the present disclosure is not limited to the embodiments described hereinbelow and may be embodied in other forms. Rather, the embodiments introduced hereinbelow are provided so that the disclosure can be made thorough and complete and that the idea of the present disclosure can be fully conveyed to those skilled in the art.

As used herein, when a component is referred to as being on another, this component may be formed directly on another, or other components may be interposed between the two. In addition, the thickness of components in the drawings may be exaggerated to describe the technical content effectively.

When terms such as first, second, and the like are used herein to describe components, such components should not be limited by these terms. These terms are only used to distinguish one component from another. The following embodiments described and illustrated herein also include complementary embodiments thereof.

In addition, when a first element (or component) is referred to as operating or being executed on a second element (or component), it should be understood that the first element (or component) operates or is executed under a condition where the second element (or component) operates or is executed, or operates or is executed through direct or indirect interaction with the second element (or component).

When an element, component, device, or system is referred to as including a component composed of a program or software, it should be understood that this element, component, device, or system includes hardware (for example, a memory, a central processing unit (CPU), and the like) required to execute or operate the program or software or other programs or software (for example, a driver required to run an operating system or hardware, and the like), unless otherwise indicated.

In addition, in implementing an element (or component), it should be understood that this element (or component) is implementable in any form of software, hardware, or a combination of software and hardware, unless otherwise indicated.

Furthermore, the terms used herein are provided to describe the embodiments but are not intended to limit the present disclosure. As used herein, the singular forms are intended to include the plural forms as well, unless otherwise indicated. When the terms such as “comprises” and/or “comprising” are used herein, stated components do not preclude the presence or addition of one or more other components.

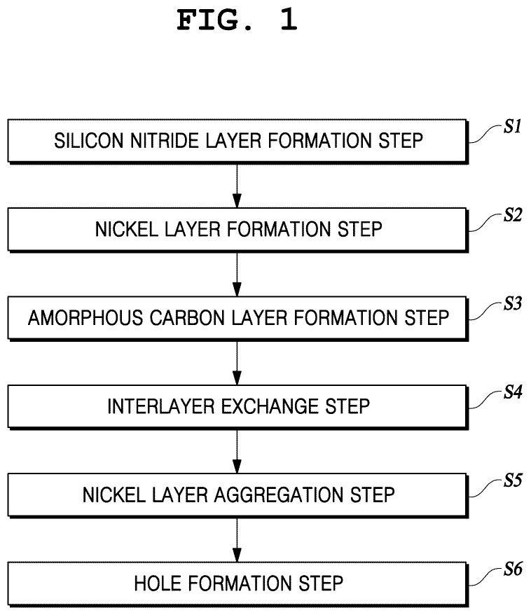

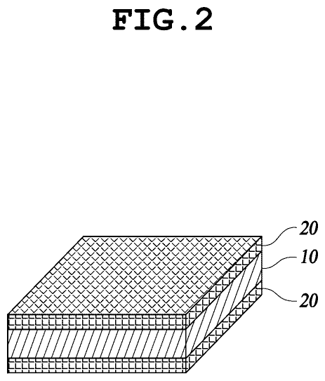

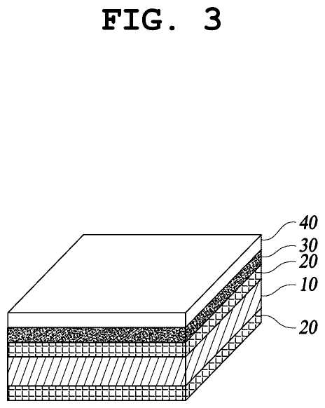

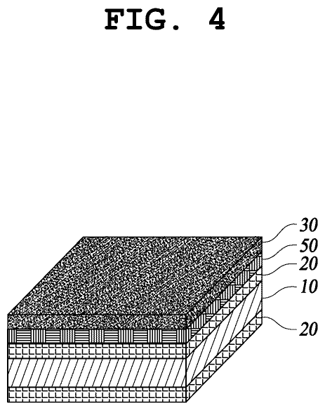

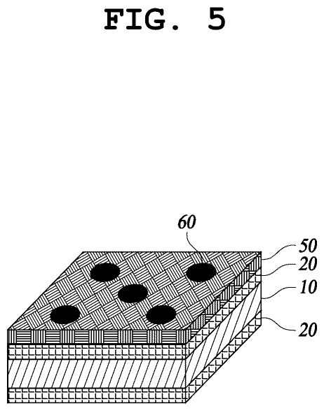

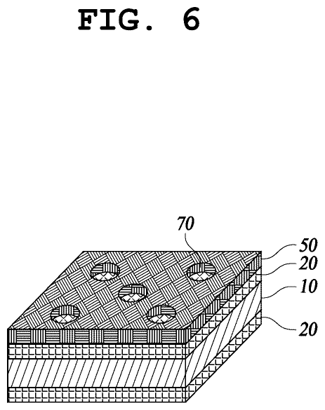

FIG. 1 is a flowchart illustrating a pellicle manufacturing method according to one embodiment of the present disclosure, FIG. 2 is a conceptual diagram schematically illustrating a step of forming silicon nitride layers in the pellicle manufacturing method according to one embodiment of the present disclosure, FIG. 3 is a conceptual diagram schematically illustrating a step of forming a nickel layer and an amorphous carbon layer in the pellicle manufacturing method according to one embodiment of the present disclosure, FIG. 4 is a conceptual diagram schematically illustrating an interlayer exchange step in the pellicle manufacturing method according to one embodiment of the present disclosure, FIG. 5 is a conceptual diagram schematically illustrating a nickel layer aggregation step in the pellicle manufacturing method according to one embodiment of the present disclosure, and FIG. 6 is a conceptual diagram schematically illustrating a hole formation step in the pellicle manufacturing method according to one embodiment of the present disclosure.

As illustrated in FIGS. 1 to 6, the pellicle manufacturing method, according to one embodiment of the present disclosure, includes a silicon nitride layer formation step (S1), a nickel layer formation step (S2), an amorphous carbon layer formation step (S3), an interlayer exchange step (S4), a nickel layer aggregation step (S5), and a hole formation step (S6).

Referring to FIG. 2, the silicon nitride layer formation step (S1) may be a step in which first and second silicon nitride layers 20 are formed on both sides of a wafer substrate 10, respectively. In one example, as shown in FIG. 2, the first and second silicon nitride layers 20 may be formed on the upper and lower portions of the wafer substrate 10, respectively.

The first and second silicon nitride layers 20 formed on the upper and lower portions of the wafer substrate 10, respectively, may be deposited through chemical vapor deposition (CVD) process, a physical vapor deposition (PVD) process, a low-pressure chemical vapor deposition (LPCVD) process, and an atomic layer deposition (ALD) process.

The silicon nitride layer 20 may inhibit the diffusion of a nickel layer 30 on the wafer substrate 10. In other words, the silicon nitride layer 20 may prevent a metal layer material or a material resistant to KOH from being diffused on the wafer substrate 10. The silicon nitride layer 20 is a compound that is deposited on the wafer substrate 10 but does not react with metal. Such a silicon nitride layer 20 may increase the adhesion to a finally formed graphene layer 50 and thus can be prevented from being detached during an etching process of the nickel layer 30 later.

Conventionally, while such a silicon nitride layer 20 is required to be deposited to a small thickness due to having low EUV transmittance, technical difficulties were significant, resulting in low yields. However, in the present disclosure, sensitivity to the deposited thickness is insignificant, so high yields are achievable.

Referring to FIG. 3, the nickel layer formation step (S2) may be a step in which the nickel layer 30 is formed on one side of the first silicon nitride layer 20 formed on one side of the wafer substrate 10. In one example, as shown in FIG. 3, the nickel layer 30 may be formed on the upper portion of the first silicon nitride layer 20 formed on the upper portion of the wafer substrate 10. The nickel layer 30 may be formed to have a thickness in the range of 1 nm to 50 nm.

In the amorphous carbon layer formation step (S3), an amorphous carbon layer 40 may be formed on one side of the nickel layer 30. In one example, as shown in FIG. 3, the amorphous carbon layer 40 may be formed on the upper portion of the nickel layer 30. The amorphous carbon layer 40 may be formed to have a thickness in the range of 1 nm to 55 nm.

When the thickness of the amorphous carbon layer 40 is referred to as ta-C while the thickness of the nickel layer 30 is referred to as tm, these layers may be deposited and formed to meet the relational expression ta-C/tm≥0.9. When the thickness of the amorphous carbon layer 40 and the thickness of the nickel layer 30 meet the relational expression described above, a uniform graphene layer 50 may grow during heat treatment.

Referring to FIGS. 3 and 4, the interlayer exchange step (S4) may be a step in which the amorphous carbon layer 40 and the nickel layer 30 are exchanged through interlayer exchange. In the interlayer exchange step (S4), the resulting wafer substrate may be heated to a first heat treatment temperature to exchange the amorphous carbon layer 40 and the nickel layer 30 through the interlayer exchange. Once the amorphous carbon layer 40 and the nickel layer 30 are exchanged through interlayer exchange, the graphene layer 50 may be formed. The first heat treatment temperature at which the interlayer exchange step (S4) is carried out may be in a temperature range of 400° C. to 600° C. in an argon gas atmosphere. That is, in the interlayer exchange step (S4), the resulting wafer substrate 10 may be placed in a furnace and heated to the first heat treatment temperature, thereby exchanging the nickel layer 30 and the amorphous carbon layer 40. As a result of exchanging the nickel layer 30 and the amorphous carbon layer 40, the graphene layer 50, which is a crystalline carbon layer, may be formed on the first silicon nitride layer 20.

Referring to FIGS. 4 and 5, the nickel layer aggregation step (S5) may be a step in which the nickel layer 30 is aggregated by heating the resulting wafer substrate 10 to a second heat treatment temperature after the interlayer exchange step (S4). The second heat treatment temperature at which the nickel layer aggregation step (S5) is carried out may be in a temperature range of 800° C. to 1100° C. That is, in the nickel layer aggregation step (S5), the wafer substrate 10 may be placed in a furnace and heated to the second heat treatment temperature, thereby aggregating the nickel layer 30. The aggregation of the nickel layer 30 may result in the size reduction of nickel aggregates 60 as the heating rate increases.

Referring to FIGS. 5 and 6, the hole formation step (S6) may be a step in which a plurality of holes 70 is formed on the graphene layer 50 in a hydrogen gas atmosphere after the nickel layer aggregation step (S5). In the hole formation step (S6), when the resulting wafer substrate 10 is placed in a furnace and heated to a temperature in the range of 800° C. to 1100° C. for 15 minutes or more in a hydrogen gas atmosphere, parts of the graphene layer 50, being in contact with the nickel aggregates 60, may be etched (Ni+C_{graphite}+H₂→Ni+CH₄).

The pellicle manufacturing method, according to one embodiment of the present disclosure, may include a nickel removal step of removing the nickel aggregates 60 after the hole formation step (S6). When the nickel aggregates 60 are etched and removed from the wafer substrate 10, the plurality of holes 70 penetrating some regions of the graphene layer 50, where the removed nickel aggregates 60 were deposited, may be formed.

In the nickel removal step, there may be remaining residues when removing the nickel using a wet etching method, so the use of an etching solution that is extremely mild and does not leave residues is preferable. To this end, sulfuric acid, hydrogen peroxide, and a heterocyclic system or nitric acid and a heterocyclic system may be used to carry out an etching process over 30 minutes to 1 hour.

According to the present disclosure, the pellicle manufacturing method based on one preferred embodiment of the present disclosure can improve transmittance characteristics while maintaining mechanical strength.

According to the present disclosure, the pellicle manufacturing method based on one preferred embodiment of the present disclosure can reduce costs and increase production efficiency because low-temperature direct growth and etching of graphene can be carried out in one chamber as a single process.

According to the present disclosure, the pellicle manufacturing method based on one preferred embodiment of the present disclosure can improve pellicle characteristics without residues and defects caused by patterning and other coatings.

Although one embodiment of the present disclosure has been disclosed hereinabove, those skilled in the art will appreciate that diverse modifications and changes are possible through supplement, alteration, deletion, or addition of components, without departing from the spirit of the present disclosure stated in the appended claims, and such modifications and changes also fall within the scope of the claims of the present disclosure.

What is claimed is:

1. A pellicle manufacturing method comprising:
forming first and second silicon nitride layers on both sides of a wafer substrate, respectively;
forming a nickel layer on one side of the first silicon nitride layer formed on one side of the wafer substrate;
forming an amorphous carbon layer on one side of the nickel layer;
exchanging the amorphous carbon layer and the nickel layer through interlayer exchange by heating the resulting wafer substrate to a first heat treatment temperature, thereby forming a graphene layer;
aggregating the nickel layer by heating the resulting wafer substrate to a second heat treatment temperature after the exchanging of the amorphous carbon layer and the nickel layer; and
forming a plurality of holes on the graphene layer in a hydrogen gas atmosphere after the aggregating of the nickel layer.

2. The pellicle manufacturing method of claim 1, wherein in the exchanging of the amorphous carbon layer and the nickel layer, the first heat treatment temperature is in a temperature range of 400° C. to 600° C. in an argon gas atmosphere.

3. The pellicle manufacturing method of claim 1, wherein in the aggregating of the nickel layer, the second heat treatment temperature is in a temperature range of 800° C. to 1100° C.

4. The pellicle manufacturing method of claim 1, wherein the forming of the plurality of holes is carried out for 15 minutes or more in a temperature range of 800° C. to 1100° C. in a hydrogen gas atmosphere.

5. The pellicle manufacturing method of claim 1, further comprising:
removing nickel aggregates obtained by aggregating the nickel layer after the forming of the plurality of holes.
